(19) United States
(12) Patent Application Publication
(10) Pub. No.: US 2020/0144086 A1
(43) Pub. Date: May 7, 2020

(54) RETICLE SUPPORT FOR A CONTAINER

(71) Applicant: ENTEGRIS, INC., Billerica, MA (US)

(72) Inventors: Anthony Mathius TIEBEN, Belle Plaine, MN (US); Shawn Daniel EGGUM, Lonsdale, MN (US); Russ V. RASCHKE, Chanhassen, MN (US); Brian WISEMAN, Glencoe, MN (US); Huaping WANG, Eden Prairie, MN (US)

(21) Appl. No.: 16/596,277

(22) Filed: Oct. 8, 2019

Related U.S. Application Data
(60) Provisional application No. 62/756,932, filed on Nov. 7, 2018.

(51) Int. Cl. H01L 21/673

(52) U.S. Cl. CPC H01L 21/67383; H01L 21/67359; H01L 21/67346

(57) ABSTRACT

A container for supporting a workpiece, the workpiece including a chamfer around upper and lower edges of the workpiece is disclosed. The container includes a door and a shell capable of coupling with the door to define an isolated environment within the container. The container includes a workpiece support mounted to the door. The workpiece support includes a support post. The support post is configured to support a workpiece at a corner of the workpiece. The support post includes a first sloping wall. A second sloping wall is at a bottom of the first sloping wall. The second sloping side wall is configured to support a workpiece. The first sloping wall and the second sloping wall are oriented with different non-zero slopes.

### CROSS-REFERENCE TO RELATED APPLICATION

This application claims the benefit of and priority to U.S. Provisional Application No. 62/756,932 filed on Nov. 7, 2018, the entirety of which is incorporated herein by reference for all purposes.

### FIELD

This disclosure relates generally to a container for transferring workpieces such as reticles in a semiconductor fab. More specifically, this disclosure relates to a support for a workpiece, such as a reticle, that supports the reticle without contacting a critical surface of the reticle.

### BACKGROUND

During fabrication of semiconductor devices, a pattern for the various layers on the semiconductor is contained on a mask called a reticle. A reticle is an optically clear quartz substrate on which a pattern has been formed by photolithography or the like. In particular, a layer of photoresist is applied on a coated reticle blank. Thereafter, the pattern for a select layer to be formed on a semiconductor wafer is transferred onto the reticle as for example by a laser pattern generator or e-beam. After the pattern is generated on the photoresist, the exposed portions of the photoresist are removed to leave the unwanted portions of the coating layer exposed. These unwanted portions are then etched away. The remaining photoresist is then removed in a process which leaves the clean pattern on the surface on the reticle. It is imperative that the surface of the reticle be maintained in a clean state, and thus critical to avoid particle generation.

### SUMMARY

This disclosure relates generally to a container for transferring workpieces such as reticles in a semiconductor fab. More specifically, this disclosure relates to a support for a workpiece, such as a reticle, that supports the reticle without contacting a critical surface of the reticle.

A container for supporting a workpiece, the workpiece including a chamfer around upper and lower edges of the workpiece is disclosed. The container includes a door and a shell capable of coupling with the door to define an isolated environment within the container. The container includes a workpiece support mounted to the door. The workpiece support includes a support post. The support post is configured to support a workpiece at a corner of the workpiece. The support post includes a pair of first sloping walls. A pair of second sloping walls are at a bottom of the pair of first sloping walls. The pair of second sloping side walls is configured to support adjoining sides of a workpiece at the corner. The pair of first sloping walls and the pair of second sloping walls are oriented with different non-zero slopes.

A container for supporting a workpiece is also disclosed. The workpiece includes a chamfer around upper and lower edges of the workpiece. The container includes a door and a shell. The shell is capable of coupling with the door to define an isolated environment. A workpiece support is secured to the door. The workpiece support includes a support post. The support post is configured to support a workpiece. The support post includes a pair of first sloping walls angled relative to each other. A pair of second sloping walls is angled relative to each other at a bottom of the pair of first sloping walls. The pair of second sloping walls is configured to support adjoining sides of the workpiece. The pair of first sloping walls and the pair of second sloping walls are oriented with different non-zero slopes.

A container for supporting a workpiece is also disclosed. The workpiece includes a chamfer around upper and lower edges of the workpiece. The container includes a door and a shell capable of coupling with the door to define an isolated environment within the container. The container includes a workpiece support mounted to the door. The workpiece support includes a support post. The support post is configured to support a workpiece. The support post consists of a pair of first sloping walls and a pair of second sloping walls at a bottom of the pair of first sloping walls. The pair of second sloping walls is configured to be an only point of contact in supporting adjoining sides of a workpiece. The pair of first sloping walls and the pair of second sloping walls are arranged with different non-zero slopes.

### BRIEF DESCRIPTION OF THE DRAWINGS

References are made to the accompanying drawings that form a part of this disclosure, and which illustrate embodiments in which the systems and methods described in this specification can be practiced.

FIG. 1A is a perspective view of a container and a workpiece prior to being seated on a support structure of the container, according to an embodiment of the disclosure.

FIG. 1B is a perspective view of the container and the workpiece of FIG. 1A when seated on the support structure of the container, according to an embodiment of the disclosure.

FIG. 2 is a plan view of the container shown in FIGS. 1A and 1B, according to an embodiment of the disclosure.

FIG. 3 is a sectional view of the container shown in FIGS. 1A and 1B taken along a line 3-3 in FIG. 2.

FIG. 4 is a sectional view of a portion of the support structure of the container shown in FIGS. 1A and 1B taken along line 3-3 in FIG. 2.

FIG. 5 is a perspective view of a portion of the support structure of the container in FIGS. 1A and 1B.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DETAILED DESCRIPTION OF THE DRAWINGS

The following detailed description should be read with reference to the drawings in which similar elements in different drawings are numbered the same. The detailed description and the drawings, which are not necessarily to scale, depict illustrative embodiments and are not intended to limit the scope of the invention. The illustrative embodiments depicted are intended only as exemplary. Selected features of any illustrative embodiment may be incorporated into an additional embodiment unless clearly stated to the contrary.

This disclosure relates generally to a container for transferring workpieces such as reticles in a semiconductor fab. More specifically, this disclosure relates to a support for a workpiece, such as a reticle, that supports the reticle without contacting a critical surface of the reticle. A container for a workpiece can be referred to as a standardized mechanical interface (SMIF) container or pod, a reticle SMIF pod, or a reticle pod. The container, as described according to the various embodiments herein, can be used to secure a reticle for use in a semiconductor or reticle fab. The term “critical surface”, as used herein, includes an upper and/or lower surface of the reticle.

During fabrication of a workpiece such as, but not limited to, a reticle, it is important to minimize particle fluxes onto the surface of the reticle on which the pattern is being formed. Any such particles can corrupt the pattern. Even after formation of the pattern and affixation of a pellicle, larger, or macro, contaminants can settle on the reticle which can interfere with pattern transference onto the semiconductor wafer.

One source of particle formation is when the workpieces are loaded into a container. During the loading process, the harder workpiece can cause denting or deforming of a relatively softer material used in the support structure for the workpiece. When the denting or deforming occurs, the particles generated can contact a critical surface of the workpiece, thereby corrupting the pattern on the workpiece. Embodiments of this disclosure are directed to a support structure that can reduce a likelihood of denting or deforming of the support structure, thereby increasing a cleanliness of the support structure and reducing chances for particle formation that could corrupt the workpiece. Specifically, embodiments of this disclosure include a support post having a first sloping wall and a second sloping wall at the bottom of the first sloping wall. When the workpiece is in a seated state, surfaces formed on the support post have modified angles and contact points with the workpiece relative to prior support structures. In an embodiment, when the workpiece is in the seated state, a greater force is required to dent or deform the contact surface formed on the second sloping wall. Consequently, this allows particle generation to be reduced, and thereby reduces particle formation on the workpiece. Under loading, the contact of the workpiece is with a larger contact area of the second sloping wall, thereby increasing a force required before further denting or deforming occurs.

As described in more detail below, in an embodiment, during a process of loading a workpiece onto a support structure, when the workpiece is being centered, a lateral force applied to the workpiece from a first sloping wall, which has a greater angle relative to a horizontal axis, is countered by a smaller lateral reaction force from a second sloping wall formed on an opposite support post that has a smaller angle relative to the horizontal axis. This facilitates the reduction of friction between the workpiece and the sloping surfaces, thereby enabling the workpiece to be centered more easily.

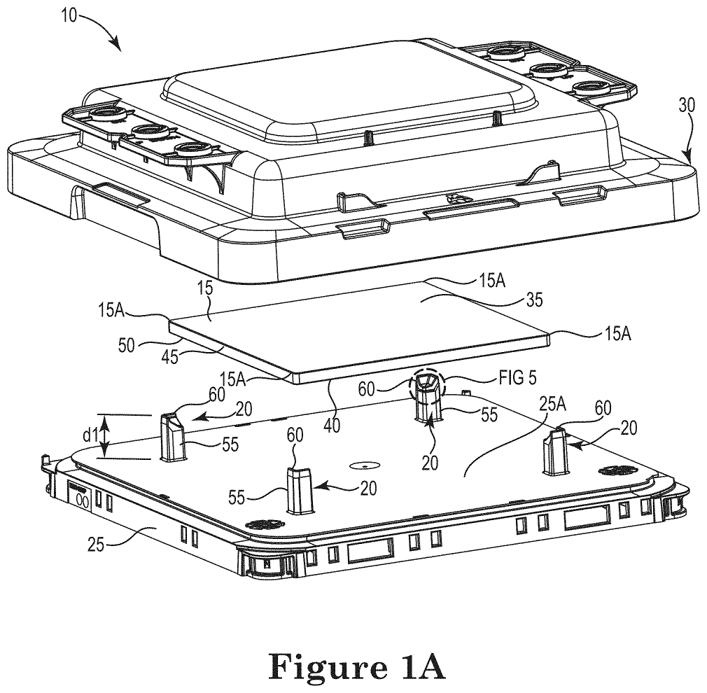

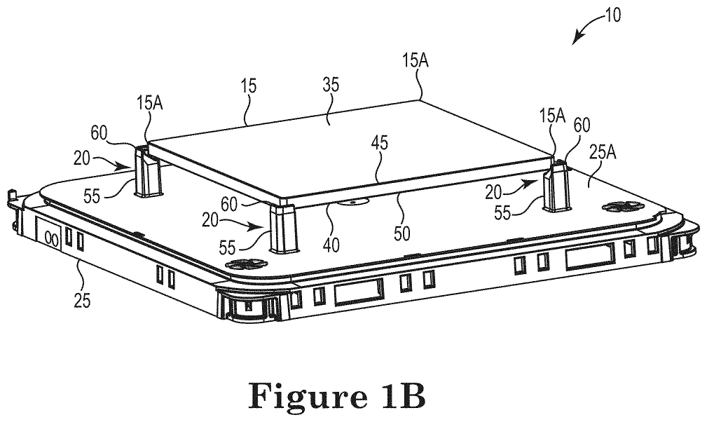

FIGS. 1A and 1B are perspective views of a container 10 and workpiece 15, according to an embodiment.

FIG. 1A is a perspective view of the container 10 and the workpiece 15 prior to being seated (e.g., in an unseated state) one or more support structures 20 of the container, according to an embodiment. FIG. 1B is a perspective view of the container 10 and the workpiece 15 of FIG. 1A when seated (e.g., in a seated state) on the one or more support structures 20 of the container 10, according to an embodiment. The container 10 includes a door 25 capable of mating with a shell 30. When the door 25 and the shell 30 are secured, a sealed, static environment is formed within the container 10 for the workpiece 15. In the illustrated embodiment, the workpiece 15 is a reticle.

The door 25 of the container 10 can be formed of a static dissipative, durable polymer, such as, but not limited to, carbon fiber-filled polycarbonate. The shell 30 of the container 10 can be formed of a durable polymer that is clear to allow the viewing of the workpiece 20. The shell 30 can also be static dissipative. A suitable example of a transparent, static dissipative material from which the shell 30 can be formed is polymethyl methacrylate. In an embodiment, the shell 30 can alternatively be formed of a static dissipative, carbon fiber-filled polycarbonate that is opaque, and include a transparent window(s) through which the workpiece can be viewed. In another embodiment, the shell 30 can be formed of clear polycarbonate, flame retardant polyetherimide, or the like. These materials for the door 25 and the shell 30 are examples. In an embodiment, the door 25 and the shell 30 can be formed of other suitable materials. In an embodiment, the door 25 and the shell 30 can be formed by injection molding or the like. In an embodiment, the door 25 and the shell 30 can include a polyetheretherketone (PEEK).

The container 10 includes one or more support structures 20 for supporting the workpiece 15. The support structure(s) 20 can be formed on or mounted to the door 25. In an embodiment, the support structure(s) 20 can be a one-piece, integral construction with the door 25. In another embodiment, the support structure(s) 20 can be molded to the door 25 in a subsequent molding procedure from the initial formation of the door 25. In yet another embodiment, the support structure(s) 20 can be mounted to the door 25 by, for example, a fastener (e.g., screw, etc.) or the like. Accordingly, the materials discussed above with respect to the door 25 are also applicable to the support structure(s) 20.

The support structure(s) 20 can be formed of a low particle generating, statically dissipative material. In an embodiment, the support structure 20 can include a thermoplastic material. In another embodiment, the support structure 20 can include a melt-processable polymer. In yet another embodiment, the support structure can include a polyetheretherketone (PEEK) having a suitable rigidity to resist denting when a force is applied by the workpiece 15 during, for example, loading of the workpiece 15 into the container 10. It is to be appreciated that the PEEK material can, for example, be a carbon-filled PEEK.

In the illustrated embodiment, four support structures 20 are shown. The support structures 20 are placed, for example, to coincide with corners 15A of the workpiece 15. It is to be appreciated that the number of support structures 20 can vary according to geometry of the workpiece 15.

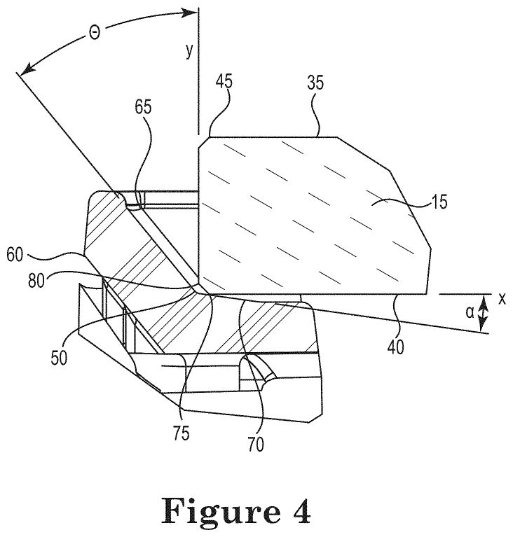

The support structures 20 are configured such that they can receive the workpiece 15 so that a critical surface of the workpiece 15 is not contacted. As defined above, the critical surface can be a top surface 35 or a bottom surface 40 of the workpiece 15. The workpiece 15 includes an upper chamfer 45 and a lower chamfer 50. The upper chamfer 45 and the lower chamfer 50 are 45° chamfers. In other words, the chamfers are formed at a 45° angle relative to the top surface 35 or bottom surface 40. It is to be appreciated that the principles described in this Specification would be applicable to chamfers other than 45°. The upper chamfer 45 and the lower chamfer 50 are shown and described in further detail in accordance with FIG. 4 below. In the depicted embodiment, the lower chamfer 50 includes an upper edge 80 and a lower edge 75.

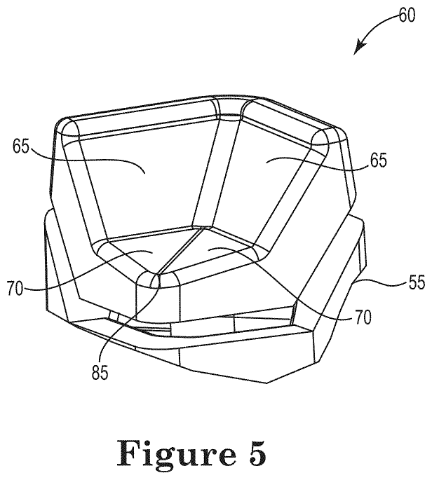

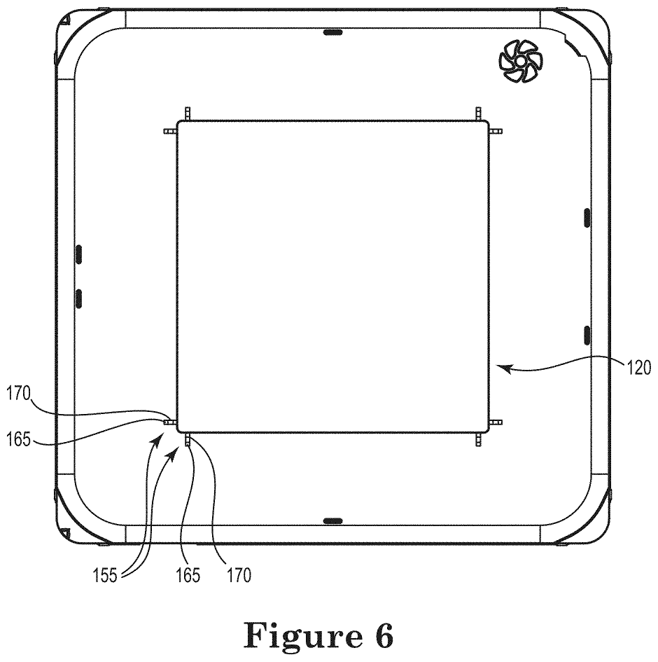

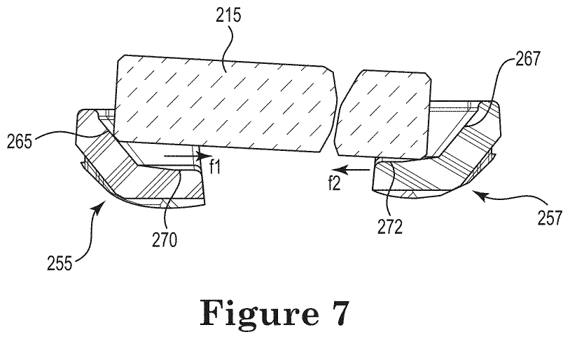

Each support structure 20 includes a post 55 extending from a surface 25A of the base 25. The post 55 extends a distance d1 from the surface 25A. The distance d1 provides a space between the bottom surface 40 of the workpiece 15 and the surface 25A when the workpiece 15 is in the seated state (FIG. 1B). Maintaining the space between the bottom surface 40 of the workpiece 15 and the surface 25A can, for example, ensure that the workpiece 15 is maintained in a clean state. In some embodiments, an industry standard distance of at or about 39.3 mm can be maintained between the bottom surface 40 of the workpiece 15 and a bottom surface of the door 25. The post 55 includes a support feature 60 at the end of the post 55. Referring to FIGS. 4 and 5, the support feature 60 includes a plurality of first sloping walls 65 and a plurality of second sloping walls 70 at a bottom of the plurality of first sloping walls 65. The first sloping walls 65 can be adjoined to or separate from the second sloping walls 70. The support feature 60 is shown and described in additional detail in accordance with FIGS. 4 and 5 below.

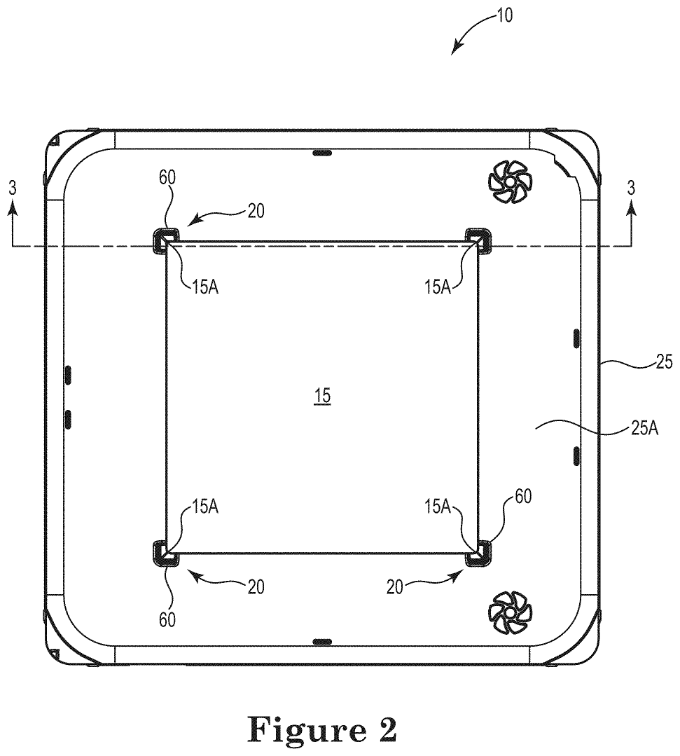

FIG. 2 is a plan view of the container 10 in FIGS. 1A and 1B, according to an embodiment. In FIG. 2, the workpiece 15 is in the seated state. Accordingly, the workpiece 15 is disposed in contact with the support feature 20 in each of the corners 15A of the workpiece 15.

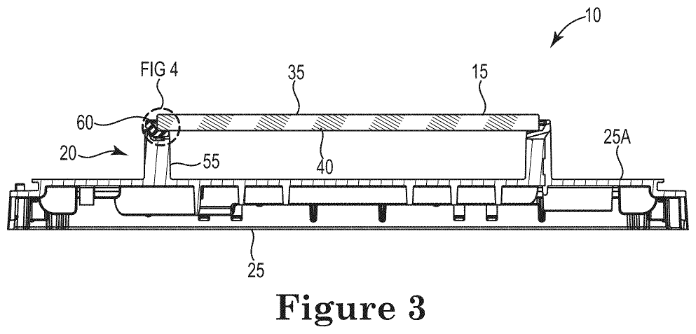

FIG. 3 is a sectional view of the container 10 in FIGS. 1A and 1B taken along a line 3-3 in FIG. 2, according to an embodiment. FIG. 4 is a sectional view of a portion of the support structure 20 of the container 10 in FIGS. 1A and 1B taken along line 3-3 in FIG. 2, according to an embodiment. FIG. 5 is a perspective view of a portion of the support structure 20 of the container 10 in FIGS. 1A and 1B, according to an embodiment.

FIGS. 3-5 will be discussed generally, unless specifically noted otherwise.

As described in more detail below in connection with FIG. 3 and FIG. 5, during a process of loading the workpiece 15 onto the support structure 20 (e.g., from the unseated state in FIG. 1A to the seated state in FIG. 1B), the workpiece 15 can come into contact with the plurality of first sloping walls 65 due to, for example, misalignment resulting from automated handling of the workpiece 15. Such contact can be along the upper edge 80 of the lower chamfer 50. As a result, particle generation, if any, is disposed away from the surface 40 of the workpiece 15. This can result in an increased ability to maintain a clean environment in the container 10. Once the workpiece 15 is moved into place (e.g., a seated state), contact with the support structure 20 is limited to a contact point along the lower edge of the lower chamfer 50.

The workpiece 15, when in the seated state, is spaced from the plurality of first sloping walls 65. The spacing is possible because the plurality of first sloping walls 65 are oriented at an angle 0 with respect to a vertical axis y. The vertical axis y is perpendicular to the surface 25A (FIGS. 1A, 1B) of the door 25 (FIGS. 1A, 1B).

In an embodiment, the angle θ is selected to be less than about 45°.

In an embodiment, the angle θ is selected to be less than about 42°.

In an embodiment, the angle θ is selected to be at or about 39°.

The angle θ can be selected so that when the workpiece 15 is being installed onto the support structures 20, if a misalignment of the workpiece 15 occurs and contact is made between the workpiece 15 and the plurality of first sloping walls 65, the contact is spaced from a lower edge 75 of the lower chamfer 50 and disposed toward an upper edge 80 of the lower chamfer 50. Advantageously, if a dent or deformation of the plurality of first sloping walls 65 occurs from the contact with the workpiece 15, the particles generated are disposed away from the bottom surface 40 of the workpiece 15. Thus, the arrangement of the plurality of first sloping walls 65 can help maintain the workpiece 15 in a clean state. Furthermore, the steep angle of the plurality of first sloping walls 65 can help reduce a likelihood of contacting the lower chamfer 50 of the workpiece 15.

In an embodiment, the plurality of first sloping walls 65 can include a curvature. That is, in an embodiment, the plurality of first sloping walls 65 can include a non-planar geometry, such as a concave surface, so long as the contact between the first sloping walls 65 and the workpiece 15 being along the upper edge 80 of the lower chamfer 50, if misalignment of the workpiece 15 occurs.

The workpiece 15, when in the seated state, contacts the plurality of second sloping walls 70 at the lower edge 75 of the lower chamfer 50. The upper edge 80 of the lower chamfer 50 is spaced from the support feature 60. In an embodiment, when the workpiece 15 is in the seated state, the lower chamfer 50 serves as the only point of contact with the support feature 60. Thus, the workpiece 15 is not in contact with the plurality of first sloping walls 65 when in the seated state.

This configuration allows particle generation to be reduced, and thereby reduces particle formation on the workpiece. This is because when prior support structures being used, a workpiece is not supported by bottom walls of a support structure, and instead supported by upper sloping walls that correspond to the first plurality of sloping walls 65 in FIGS. 3 and 4. Compared to prior support structures in which the contact surface is formed on upper sloping walls, the embodiment illustrated in FIGS. 3 and 4 requires a greater force to dent or deform the contact surface formed on the plurality of second sloping walls 70. Consequently, this allows particle generation to be reduced, and thereby reduces particle formation on the workpiece.

The plurality of second sloping walls 70 are angled at an angle a with respect to a horizontal axis x. The horizontal axis x is parallel to the surface 25A of the door 25.

In an embodiment, the angle α is selected to be greater than 0°.

In an embodiment, the angle α is selected to be greater than 0° and less than about 15°.

In an embodiment, the angle α is selected to be greater than 0° and less than about 10°.

In an embodiment, the angle α is selected to be greater than at or about 6° and less than at or about 15°.

In an embodiment, the angle α is selected to be at or about 8°.

The angle a can be selected to prevent the bottom surface 40 of the workpiece 15 from physically contacting the plurality of second sloping walls 70. As such, a slope of the plurality of second sloping walls 70 is not equal to zero. That is, the plurality of second sloping walls 70 have a non-zero slope.

In an embodiment, the plurality of second sloping walls 70 can include a curvature. That is, in an embodiment, the plurality of second sloping walls 70 can include a non-planar geometry, such as a concave surface, so long as no physical contact occurs between the bottom surface 40 of the workpiece 15 and the plurality of second sloping walls 70 when the workpiece 15 is in the seated state.

In an embodiment, the contact point of the support structures 20 and the workpiece 15 being on the plurality of second sloping walls 70 can maintain the workpiece 15 in a secure position to restrain the workpiece 15 from moving in directions that is, for example, parallel to the surface 25A of the door 25.

A simulation to identify a critical force at which denting or deformation of the plurality of second sloping walls 70 was performed using finite element analysis utilizing software commercially available from ANSYS®. For the simulation, ANSYS Mechanical Version 19.1 was utilized. As input parameters, the simulation utilized: geometry of the plurality of second sloping walls 70; material properties of the material forming the plurality of second sloping walls 70; dimensions of the workpiece 15; and hardness properties of the workpiece 15. A force applied to the workpiece 15 was simulated. In the simulation, a critical force resulting in deformation was estimated to be at or about 3.60 pounds. Conversely, utilizing the same simulation and geometry of a current support structure in which contact is along the first plurality of sloping walls, the resulting critical force was 2.17 pounds. That is, the simulated design according to this Specification resulted in a 65% increase in the critical force.

It is to be appreciated that the angle θ or the angle a can be controlled as discussed above. That is, in an embodiment, the angle θ can be maintained closer to 45° when the angle a is greater than 0° . In an embodiment, reducing the angle θ to be less than 45° can increase an effectiveness of the support structures 20 in preventing particle formation on the workpiece 15.

Because the support feature 60 is arranged as a corner, the feature can be symmetrical along a line 85 which is a line of symmetry for the support feature 60. In an embodiment, the support feature 60 is not symmetrical.

Referring to FIG. 6, in an alternative embodiment, a support structure 120 includes eight support posts 155 and each of the support posts 155 has a first sloping wall 165 and a second sloping wall 170. It is to be understood that the number of support posts of a support structure can vary, and each support post can include one or more first sloping walls and one or more second sloping walls. It is also to be understood that if a support post includes two or more first sloping walls, the first sloping walls can be adjoined or disjoined as desired.

Referring to FIG. 7, in an embodiment, the support structure includes a first support post 255 and a second support post 257 located opposite to the first support post 255. The first support post 255 includes a first sloping wall 265 and a second sloping wall 270. The second support post 257 includes a first sloping wall 267 and a second sloping wall 272. During a process of loading a workpiece 215 onto the support structure, when the workpiece 215 is being centered, a lateral force f1 applied to the workpiece from the first sloping wall 265 of the first support post 255, which has a greater angle relative to a horizontal axis, is countered by a smaller lateral reaction force f2 from the second sloping wall 272 of the second support post 272 that has a smaller angle relative to the horizontal axis. This allows friction between the workpiece 215 and the sloping surfaces 265, 270 to be reduced, thereby allowing the workpiece 215 to be centered more easily.

Aspects:

It is to be appreciated that any one of aspects 1-8 can be combined with any one of aspects 9-14, 15-23, or 24. Any one of aspects 9-14 can be combined with any one of aspects 15-23 or 24. Any one of aspects 15-23 can be combined with aspect 24.

Aspect 1. A container for supporting a workpiece, the workpiece including a chamfer around upper and lower edges of the workpiece, the container including a door and a shell capable of coupling with the door to define an isolated environment within the container, the container comprising: a workpiece support mounted to the door, the workpiece support including a support post, the support post configured to support a workpiece at a corner of the workpiece, the support post including: a first sloping wall; and a second sloping wall at a bottom of the first sloping wall, the second sloping side wall configured to support adjoining sides of a workpiece at the corner, wherein the first sloping wall and the second sloping wall are oriented with different non-zero slopes.

Aspect 2. The container of aspect 1, wherein the first sloping wall is oriented at an angle relative to a vertical axis that is at or about 45° or less.

Aspect 3. The container of any one of aspects 1 or 2, wherein the second sloping wall is oriented at an angle relative to a horizontal axis that is greater than at or about 0° and at or about 15° or less.

Aspect 4. The container of any one of aspects 1-3, wherein in a seated state, the second sloping wall is configured to engage a workpiece at a lower edge of a chamfer around a lower edge of the workpiece.

Aspect 5. The container of any one of aspects 1-4, wherein the workpiece is a reticle.

Aspect 6. The container of any one of aspects 1-5, wherein the support post includes a thermoplastic material.

Aspect 7. The container of any one of aspects 1-6, wherein the workpiece support includes four support posts.

Aspect 8. The container of any one of aspects 1-7, wherein one or more of the first sloping wall and the second sloping wall includes a curved, non-planar surface.

Aspect 9. A container, for supporting a workpiece, the workpiece including a chamfer around upper and lower edges of the workpiece, the container comprising: a door and a shell, the shell capable of coupling with the door to define an isolated environment; a workpiece support secured to the door, the workpiece support including a support post, the support post configured to support a workpiece, the support post including: a first sloping wall angled relative to each other; and a second sloping wall angled relative to each other at a bottom of the first sloping wall, the second sloping wall configured to support adjoining sides of the workpiece, wherein the first sloping wall and the second sloping wall are oriented with different non-zero slopes.

Aspect 10. The container of aspect 9, wherein the workpiece is a reticle.

Aspect 11. The container of any one of aspects 9 or 10, wherein the reticle is sandwiched between the workpiece support and the shell when the shell is coupled to the door.

Aspect 12. The container of any one of aspects 9-11, wherein the first sloping wall is oriented at an angle relative to a vertical axis that is at or about 45° or less.

Aspect 13. The container of any one of aspects 9-12, wherein the second sloping wall is oriented at an angle relative to a horizontal axis that is greater than at or about 0° and at or about 15° or less.

Aspect 14. The container of any one of aspects 9-13, wherein one or more of the first sloping wall and the second sloping wall includes a curved, non-planar surface.

Aspect 15. A container for supporting a workpiece, the workpiece including a chamfer around upper and lower edges of the workpiece, the container including a door and a shell capable of coupling with the door to define an isolated environment within the container, the container comprising: a workpiece support mounted to the door, the workpiece support including a support post, the support post configured to support a workpiece, the support post consisting of: a pair of first sloping walls; and a pair of second sloping walls at a bottom of the pair of first sloping walls, the pair of second sloping walls configured to be an only point of contact in supporting adjoining sides of a workpiece, wherein the pair of first sloping walls and the pair of second sloping walls are arranged with different non-zero slopes.

Aspect 16. The container of aspect 15, wherein the pair of first sloping walls is oriented at an angle relative to a vertical axis that is at or about 45° or less.

Aspect 17. The container of any one of aspects 15 or 16, wherein the pair of second sloping walls is oriented at an angle relative to a horizontal axis that is greater than at or about 0° and at or about 15° or less.

Aspect 18. The container of any one of aspects 15-17, wherein in a seated state, the pair of second sloping walls is configured to engage a workpiece at a lower edge of a chamfer around a lower edge of the workpiece.

Aspect 19. The container of any one of aspects 15-18, wherein the workpiece is a reticle.

Aspect 20. The container of any one of aspects 15-19, wherein the support post includes a thermoplastic material.

Aspect 21. The container of any one of aspects 15-20, wherein the workpiece support includes four support posts.

Aspect 22. The container of any one of aspects 15-21, wherein in an unseated state, the pair of first sloping walls is oriented such that an incidental contact with a workpiece is disposed at an upper edge of a chamfer around a lower edge of the workpiece.

Aspect 23. The container of any one of aspects 15-22, wherein one or more of the pairs of first sloping walls and the pair of second sloping walls includes a curved, non-planar surface.

Aspect 24. A container assembly, comprising: a workpiece, the workpiece including a chamfer around upper and lower edges of the workpiece, the container including a door and a shell capable of coupling with the door to define an isolated environment within the container, the container including: a workpiece support mounted to the door, the workpiece support including a support post, the support post configured to support a workpiece, the support post consisting of: a first sloping wall; and a second sloping wall at a bottom of the first sloping wall, the second sloping wall configured to be an only point of contact in supporting adjoining sides of a workpiece, wherein the first sloping wall and the second sloping wall are arranged with different non-zero slopes.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. A container for supporting a workpiece comprising:
a door and a shell, the shell capable of coupling with the door to define an isolated environment;
a workpiece support secured to the door, the workpiece support including a support post configured to support a workpiece, the support post including:
a first sloping wall; and
a second sloping wall at a bottom of the first sloping wall, the second sloping wall configured to support a workpiece,
wherein the first sloping wall and the second sloping wall are oriented with different non-zero slopes.

2. The container of claim 1, wherein the first sloping wall is oriented at an angle relative to a vertical axis that is at or about 45° or less.

3. The container of claim 1, wherein the second sloping wall is oriented at an angle relative to a horizontal axis that is greater than at or about 0° and at or about 15° or less.

4. The container of claim 1, wherein one or more of the first sloping wall and the second sloping wall includes a curved, non-planar surface.

5. The container of claim 1, wherein the first sloping wall is adjoined to or separated from the second sloping wall.

6. A container for supporting a workpiece comprising:
a door;
a shell capable of coupling with the door to define an isolated environment within the container;
a workpiece support mounted to the door, the workpiece support including a support post, the support post configured to support a workpiece, the support post including sloping walls that consist of:
a pair of first sloping walls; and
a pair of second sloping walls at a bottom of the pair of first sloping walls, the pair of second sloping walls configured to be an only point of contact in supporting a workpiece,
wherein the pair of first sloping walls and the pair of second sloping walls are arranged with different non-zero slopes.

7. The container of claim 6, wherein the pair of first sloping walls is oriented at an angle relative to a vertical axis that is at or about 45° or less.

8. The container of claim 6, wherein the pair of second sloping walls is oriented at an angle relative to a horizontal axis that is greater than at or about 0° and at or about 15° or less.

9. The container of claim 6, wherein in a seated state, the pair of second sloping walls is configured to engage a workpiece at a lower edge of a chamfer around a lower edge of the workpiece.

10. The container of claim 6, wherein in an unseated state, the pair of first sloping walls is oriented such that an incidental contact with a workpiece is disposed at an upper edge of a chamfer around a lower edge of the workpiece.

11. The container of claim 6, wherein one or more of the pair of first sloping walls and the pair of second sloping walls includes a curved, non-planar surface.

12. The container of claim 6, wherein the pair of first sloping walls is adjoined to or separated from the pair of second sloping walls.
